(19) United States
(12) Patent Application Publication
(10) Pub. No.: US 2007/0259503 A1
(43) Pub. Date: Nov. 8, 2007

(54) METHOD OF FABRICATING A SEMICONDUCTOR DEVICE

(75) Inventors: Hui-Chen Chang, Taoyuan County (TW); Tony Lin, Hsinchu City (TW); Brook Hsu, Hsinchu County (TW); Cyrus LW Chen, Yilan County (TW); Meng-Lin Lee, Changhua County (TW); Wei-Tsun Shiau, Kaohsiung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 11/777,291

(22) Filed: Jul. 13, 2007

Related U.S. Application Data
(62) Division of application No. 11/308,390, filed on Mar. 21, 2006.

(51) Int. Cl. H01L 21/336

(52) U.S. Cl. 438/303; 257/E21.409

(57) ABSTRACT

A method of fabricating a semiconductor device is provided herein. The semiconductor device includes a substrate, a gate dielectric layer, a gate, a pair of source/drain regions and a stressed layer. The gate dielectric layer is disposed on the substrate and the gate whose top area is larger than its bottom area is disposed on the gate dielectric layer. The source/drain regions are disposed in the substrate next to the sidewalls of the gate. The stressed layer is disposed on the substrate to cover the gate and the source/drain regions.

### CROSS-REFERENCE TO RELATED APPLICATION

This application is a divisional of an application Ser. No. 11/308,390, filed Mar. 21, 2006, now pending. The entirety of each of the above-mentioned patent application is hereby incorporated by reference herein and made a part of this specification.

### BACKGROUND OF THE INVENTION

1. Field of the Invention

The present invention relates to a semiconductor device and fabricating method thereof. More particularly, the present invention relates to a semiconductor device and fabricating method thereof that can improve the operating efficiency of the semiconductor device by controlling partial mechanical stress.

2. Description of the Related Art

In semiconductor production, the dimensions of semiconductor devices are often reduced to attain a higher operating speed and a lower power consumption. However, with the ever-increasing level of integration of devices, the miniaturization of the devices has almost reached a limit. Hence, other means of reducing the dimensions of semiconductor devices are required to increase the operating speed and reduce the power consumption.

To that end, a technique that resolves the dimension miniaturization limit of a device is provided through controlling the stress in the semiconductor transistor channel region. In this method, stress is used to change the gap in the crystal lattice and hence increase the migration rate of the carriers.

The most common method of controlling the channel stress is to use a compressive-stressed silicon-germanium (Si—Ge) layer as the channel region of a PMOS transistor and a tensile-strained silicon (Si) layer as the channel region of an NMOS transistor so that the gap in the crystal lattice is adjusted. Hence, the migration rate of the carriers is increased. However, in fabricating a complementary metal-oxide-semiconductor (CMOS) transistor, the process of forming the aforementioned channel regions simultaneously is quite complicated. Furthermore, when the silicon-germanium layer undergoes a thermal treatment, the dislocation phenomena or the severance of the germanium atoms may bring down the characteristic of the breakdown voltage of the gate.

In recent years, a closely related technique for controlling partial mechanical stress has been developed. The method utilizes the silicon nitride layer as an etching stop layer for fabricating a contact to generate stress in the channel region, thereby affecting the size of the driving current and improving the migration rate of the carriers.

Although the aforementioned method of controlling the partial mechanical stress is simple to operate, the extent to which the stress in the channel region is improved is still quite limited.

### SUMMARY OF THE INVENTION

Accordingly, at least one objective of the present invention is to provide a semiconductor device capable of effectively increasing the migration rate of electrons so that the device can have higher operating speed and lower power consumption.

At least a second objective of the present invention is to provide a method of fabricating a semiconductor device capable of increasing stress in the channel region so that the device can have higher operating speed and lower power consumption.

To achieve these and other advantages and in accordance with the purpose of the invention, as embodied and broadly described herein, the invention provides a semiconductor device. The semiconductor device comprises a substrate, a gate dielectric layer, a gate, a pair of source/drain regions and a stressed layer. The gate dielectric layer is disposed on the substrate and the gate whose top area is larger than its bottom area is disposed on the gate dielectric layer. The source/drain regions are disposed in the substrate next to the sidewalls of the gate. The stressed layer is disposed on the substrate to cover the gate and the source/drain regions.

According to one embodiment of the present invention, the semiconductor device further includes lightly doped region disposed in the substrate between the source/drain regions and the gate.

According to one embodiment of the present invention, the semiconductor device further includes a halo implant region disposed in the substrate underneath a lightly doped region.

According to one embodiment of the present invention, the semiconductor device further includes a metal silicide layer disposed between the gate and the stressed layer and between the source/drain regions and the stressed layer.

According to one embodiment of the present invention, the substance constituting the metal silicide layer in the semiconductor device is comprising titanium silicide, tungsten silicide, cobalt silicide, nickel silicide, molybdenum silicide or platinum silicide.

According to one embodiment of the present invention, the substance constituting the stressed layer in the semiconductor device is comprising silicon nitride, silicon oxide or silicon oxynitride.

According to one embodiment of the present invention, the semiconductor device further includes a liner oxide layer disposed on the sidewalls of the gate.

According to one embodiment of the present invention, the substance constituting the liner oxide layer in the semiconductor device includes silicon oxide.

According to one embodiment of the present invention, the substance constituting the gate of the semiconductor device includes doped polysilicon.

According to one embodiment of the present invention, the substrate comprises a silicon substrate or a silicon on insulator (SOI) substrate.

The present invention also provides a method of fabricating a semiconductor device. First, a substrate is provided and then a gate dielectric layer and a conductive layer are sequentially formed over the substrate. A patterned photoresist layer is formed over the conductive layer. Using the patterned photoresist layer as a mask, an etching operation is carried out to remove a portion of the conductive layer and a portion of the gate dielectric layer to form a gate whose top surface is larger than its bottom surface. Thereafter, the patterned photoresist layer is removed and then a spacer is formed on the sidewalls of the gate. After that, a source region and a drain region is formed in the substrate next to the spacers and then the spacers are removed. Lastly, a stressed layer is formed over the substrate to cover the gate and the source/drain regions.

According to the aforementioned method of fabricating the semiconductor device in one embodiment of the present invention, the etching operation is a series of etching processes by using two groups of etching gases with different proportions.

According to the aforementioned method of fabricating the semiconductor device in one embodiment of the present invention, the two groups of etching gas used in the etching operation are a first group comprising chlorine (Cl₂) and oxygen (O₂) and a second group comprising hexafluoro-ethane (C₂F₆), hydrogen bromide (HBr) and helium (He).

According to the aforementioned method of fabricating the semiconductor device in one embodiment of the present invention, after removing the patterned photoresist layer, the method further includes forming a lightly doped region in the substrate on the two sides of the gate.

According to the aforementioned method of fabricating the semiconductor device in one embodiment of the present invention, the lightly doped region is formed by performing an ion implant process.

According to the aforementioned method of fabricating the semiconductor device in one embodiment of the present invention, after forming the lightly doped region, the method further includes forming a halo implant region in the substrate underneath the lightly doped region.

According to the aforementioned method of fabricating the semiconductor device in one embodiment of the present invention, the method of forming the halo implant region includes performing a tilt ion implant process.

According to the aforementioned method of fabricating the semiconductor device in one embodiment of the present invention, after removing the patterned photoresist layer, the method further includes forming a liner oxide layer on the sidewalls of the gate.

According to the aforementioned method of fabricating the semiconductor device in one embodiment of the present invention, the method of forming the liner oxide layer includes performing a thermal oxidation process.

According to the aforementioned method of fabricating the semiconductor device in one embodiment of the present invention, after forming the source/drain regions but before forming the spacers, the method further includes forming a metal silicide layer over the gate and the source/drain regions.

According to the aforementioned method of fabricating the semiconductor device in one embodiment of the present invention, the method of forming the stressed layer includes performing a chemical vapor deposition process.

Because the stressed layer in the semiconductor device and the aforementioned method of fabricating the semiconductor device of the present invention effectively increases the stress in the channel region, the semiconductor device can have a higher operating speed and a lower power consumption. In addition, the contact area between the gate and the gate dielectric layer in the semiconductor device is reduced. Hence, the overlap capacitance between the gate and the source/drain regions is also reduced. Furthermore, in the method of fabricating the semiconductor device according to the present invention, a halo implanted region can be formed in the substrate for effectively suppressing the short channel effect.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a semiconductor device according to one embodiment of the present invention.

FIGS. 2A through 2E are schematic cross-sectional views showing the steps for fabricating a semiconductor device according to one embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

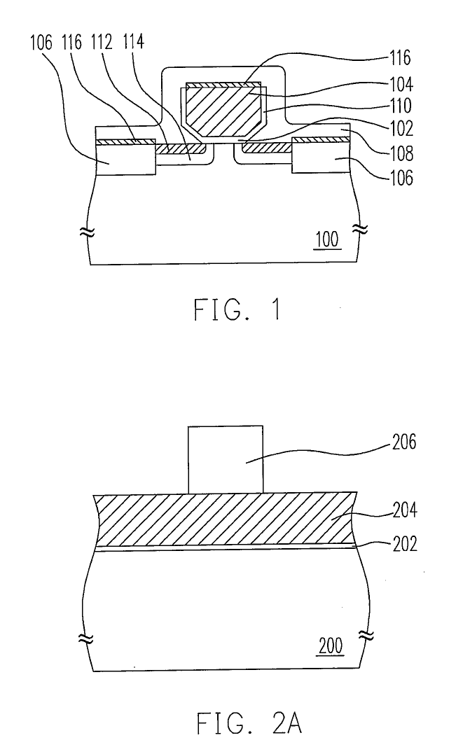

FIG. 1 is a schematic cross-sectional view of a semiconductor device according to one embodiment of the present invention. As shown in FIG. 1, the semiconductor device is an NMOS transistor, for example. The semiconductor device comprises a semiconductor substrate 100, a gate dielectric layer 102, a gate 104, a pair of source/drain regions 106, a stressed layer 108, a liner oxide layer 110, a lightly doped region 112, a halo implant region 114 and a metal silicide layer 116.

The semiconductor substrate 100 is a silicon substrate or a SOI substrate, for example. The gate dielectric layer 102 is disposed on the semiconductor substrate 100 and fabricated using silicon oxide, for example.

The gate 104 is disposed on the gate dielectric layer 102 and fabricated using doped polysilicon, for example. Furthermore, the gate 104 has a top surface area greater than its bottom surface area. Hence, the contact area between the gate 104 and the gate dielectric layer 102 is reduced and the overlap capacitance between the gate and the source/drain regions is lowered. Although the cross section of the gate 104 is hexagonal in the present embodiment, this should by no means restrict the scope of the present invention. In other words, there is no particular specification for the cross-sectional shape of the gate as long as the top area is larger than the bottom area. For example, the gate can have a trapezoidal cross section.

The source/drain regions 106 are disposed in the semiconductor substrate 100 on each side of the gate 104. The source/drain regions 106 are formed, for example, by performing an ion implant process using phosphorus as the dopants.

The stressed layer 108 is disposed on the semiconductor substrate 100 to cover the gate 104 and the source/drain regions 106. The stressed layer 108 is fabricated using silicon nitride, silicon oxide or silicon oxynitride in a chemical vapor deposition process, for example. The NMOS transistor is used in the present embodiment as an example, so the stressed layer is a film layer having tensile stress. On the other hand, if the semiconductor device is a PMOS transistor, then the stressed layer is a film layer having compressive stress.

The liner oxide layer 110 is disposed on the sidewalls of the gate 104. The liner oxide layer 110 is a silicon oxide layer formed, for example, formed by performing a thermal oxidation process.

The lightly doped regions 112 are disposed in the semiconductor substrate 100 between the source/drain regions 106 and the gate 104. The lightly doped regions 112 are formed, for example, by performing an ion implant process using phosphorus as the dopants.

The halo implant region 114 is disposed in the semiconductor substrate 100 underneath the lightly doped region 108. The halo implant region 114 is formed, for example, by performing a tilted ion implant process using boron as the dopants. The halo implant region 114 serves to constraint the short channel effect.

The metal silicide layer 116 is disposed between the gate 104 and the stressed layer 108 and between the source/drain regions 106 and the stressed layer 108. The metal silicide layer 116 is fabricated using titanium silicide, tungsten silicide, cobalt silicide, nickel silicide, molybdenum silicide or platinum silicide for lowering material resistance value.

In the semiconductor device of the present invention, the top surface of the gate 104 has an area greater than the bottom surface so that the lower portion of the gate 104 has a recess profile. Hence, the stressed layer 108 can directly apply a stress to the channel region (not labeled) and increase the stress there to achieve a higher operating speed and a lower power consumption.

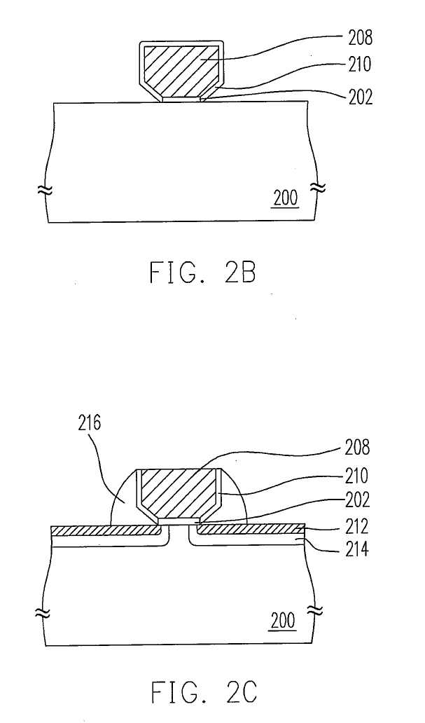

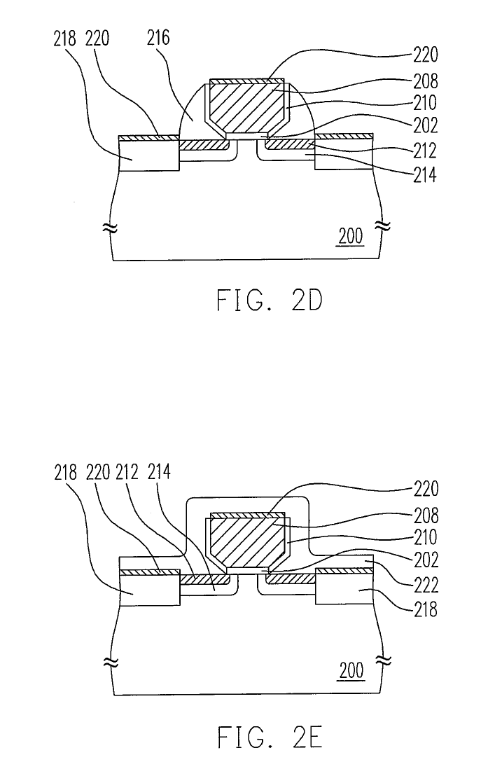

FIGS. 2A through 2E are schematic cross-sectional views showing the steps for fabricating a semiconductor device according to one embodiment of the present invention. The semiconductor device in the present invention is an NMOS transistor, for example. First, as shown in FIG. 2A, a semiconductor substrate 200 is provided. The semiconductor substrate 200 from the bottom up has a gate dielectric layer 202 and a conductive layer 204 already formed thereon. Then, a patterned photoresist layer 206 is formed over the conductive layer 204. The gate dielectric layer 202 is fabricated using silicon oxide in a thermal oxidation process, for example. The conductive layer 204 is a doped polysilicon layer formed, for example, by performing a chemical vapor deposition process with in-situ doping.

As shown in FIG. 2B, using the patterned photoresist layer 206 as a mask, an etching operation is carried out to remove a portion of the conductive layer 204 and the gate dielectric layer 202 to form a gate 208. The top surface of the gate 204 has an area greater than its bottom surface. The etching operation uses two groups of etching gas, for example. The two groups of etching gas used in the etching operation are a first group comprising chlorine (Cl₂) and oxygen (O₂) and a second group comprising hexafluoro-ethane (C₂F₆), hydrogen bromide (HBr) and helium (He). By adjusting the ratio of the two groups of etching gas in the etching operation, the gate 208 having the shape shown in FIG. 2B is formed. With a reduced contact area between the gate 208 and the gate dielectric layer 202, the overlap capacitance between the gate and the source/drain regions is reduced. Although the cross section of the gate 208 is hexagonal in the present embodiment, this should by no means restrict the scope of the present invention. After forming the gate 208, the patterned photoresist layer 206 is removed. And then, an additional liner oxide layer 210 may be formed over the sidewalls of the gate 208. The liner oxide layer 210 can be a silicon oxide layer formed, for example, by performing a thermal oxidation process.

As shown in FIG. 2C, a lightly doped region 212 is formed in the semiconductor substrate 200 on each side of the gate 208. The lightly doped drain region 212 is formed, for example, by performing an ion implant process using phosphorus as the dopants.

Thereafter, a halo implant region 214 is formed in the semiconductor substrate 200 underneath the lightly doped region 212. The method of forming the halo implant region 214 includes performing a tilted ion implant process using boron as the dopants, for example. The halo implant region 214 provides an effective means of suppressing the short channel effect. After that, spacers 216 made of silicon nitride are formed on the sidewalls of the gate 208.

As shown in FIG. 2D, source/drain regions 218 are formed in the semiconductor substrate 200 next to the spacers 216. The method of forming the source/drain regions 218 includes, for example, performing an ion implantation using phosphorus as the dopants. Furthermore, a rapid thermal annealing operation may be carried out on the semiconductor substrate 200 to re-align the crystal lattice near the surface of the semiconductor substrate 200 to compensate the crystal lattice defect by the ion implantation. Meanwhile, the lightly doped region 212 and the halo implant region 214 can be driven in the substrate under the gate by the diffusion effect.

Thereafter, a metal silicide layer 220 is formed on the gate 208 and the source/drain regions 218. The metal silicide layer 220 can be fabricated using titanium silicide, tungsten silicide, cobalt silicide, nickel silicide, molybdenum silicide or platinum silicide. The method of forming the metal silicide layer 220 includes depositing a metallic material over the substrate 200 to form a conformal metallic material layer (not shown). Thereafter, a thermal processing operation is carried out to form a layer of self-aligned metal silicide 220 over the gate 208 and the source/drain regions 218. Lastly, the metallic material not participating in the reaction is removed.

As shown in FIG. 2E, the spacers 216 are removed by performing a wet etching operation, for example. Thereafter, a stressed layer 222 is formed over the semiconductor substrate 200 to cover the gate 208 and the source/drain regions 218. The stressed layer 222 can be fabricated using silicon nitride, silicon oxide or silicon oxynitride. The method of forming the stressed layer 222 includes, for example, performing a chemical vapor deposition process. The NMOS transistor is used in the present embodiment as an example, so the stressed layer is a film layer having tensile stress. On the other hand, if the semiconductor device is a PMOS transistor, then the stressed layer is a film layer having compressive stress. The stressed layer 222 can be a tensile stressed layer or a compressive stressed layer by controlling the factors necessary for forming the stressed layer such as the temperature, the pressure and the ratio between processing gases. Since the conditions for setting the stress in the stressed layer is familiar to those skilled in this areas, a detailed description is omitted.

In the method of fabricating a semiconductor device according to the present invention, the top surface of the gate 208 has an area greater than the bottom surface. Hence, the stressed layer 222 can directly apply a stress to the channel region and increase the stress there to achieve a higher operating speed and a lower power consumption.

Although NMOS transistor is used as an example in the aforementioned embodiment, this should by no means limit the scope of the present invention as such. Anyone familiar in this area may expand from the embodiment and apply it to other semiconductor devices including the PMOS transistors or the CMOS transistors as well.

In summary, the present invention has at least the following advantages:
1. In the semiconductor device and the fabrication method thereof according to the present invention, the stressed layer can increase the stress in the channel region to achieve a higher speed and less power consumption.
2. In the method of fabricating the semiconductor device, a halo implant region can be formed for suppressing the short channel effect.
3. The contact area between the gate and the gate dielectric layer in the semiconductor device is effectively minimized so that the overlap capacitance between the gate and the source/drain regions can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a semiconductor device, comprising:
providing a substrate having a gate dielectric layer and a conductive layer sequentially stacked thereon;
forming a patterned photoresist layer over the conductive layer;
performing an etching operation using the patterned photoresist layer as a mask to remove a portion of the conductive layer to form a gate and then remove a portion of the gate dielectric layer, wherein the gate has a top surface whose area is greater than its bottom surface;
removing the patterned photoresist layer;
forming a spacer on the sidewalls of the gate;
forming a source/drain region in the substrate next to the spacers;
removing the spacers; and
forming a stressed layer on the substrate to cover the gate and the source/drain regions.

2. The method of claim 1, wherein the step of performing the etching operation includes using two groups of etching gas.

3. The method of claim 2, wherein the first group of etching gas comprises chlorine (Cl₂) and oxygen (O₂) and the second group of etching gas comprises hexafluoro-ethane (C₂F₆), hydrogen bromide (HBr) and helium (He).

4. The method of claim 1, wherein after removing the patterned photoresist layer, the method further comprises forming a lightly doped region in the substrate on each side of the gate.

5. The method of claim 4, wherein the step of forming the lightly doped region comprises performing an ion implant process.

6. The method of claim 4, wherein after forming the lightly doped region, the method further comprises forming a halo implant in the substrate underneath the lightly doped region.

7. The method of claim 6, wherein the step of forming the halo implant region comprises performing a tilted ion implant process.

8. The method of claim 1, wherein after removing the patterned photoresist layer, the method further comprises forming a liner oxide layer on the sidewalls of the gate.

9. The method of claim 8, wherein the step of forming the liner oxide layer comprises performing a thermal oxidation process.

10. The method of claim 1, wherein after the forming the source/drain regions but before forming the spacers, the method further comprises forming a metal silicide layer over the gate and the source/drain regions.

11. The method of claim 1, wherein the step of forming the stressed layer comprises performing a chemical vapor deposition process.
